(19) United States
(12) Patent Application Publication
(10) Pub. No.: US 2019/0281721 A1
(43) Pub. Date: Sep. 12, 2019

(54) ELECTRONIC DEVICE

(71) Applicant: PEGATRON CORPORATION, Taipei City (TW)

(72) Inventors: Ping-Chung Wu, Taipei City (TW); Wei-Chun Tsao, Taipei City (TW); Yao-Chiang Yang, Taipei City (TW)

(73) Assignee: PEGATRON CORPORATION, Taipei City (TW)

(21) Appl. No.: 16/199,689

(22) Filed: Nov. 26, 2018

(30) Foreign Application Priority Data
Mar. 8, 2018 (TW) 107107963

(51) Int. Cl. H05K 7/14; H05K 7/10; H05K 7/02; H05K 1/02; G06F 13/42

(52) U.S. Cl. CPC H05K 7/1407; H05K 7/10; H05K 7/026; G06F 2213/0026; H05K 1/0216; G06F 13/4221; H05K 1/0215

(57) ABSTRACT

An electronic device includes a circuit board and a conductive piece. The circuit board includes a hole and a grounding pad close to the hole. The conductive piece includes an insertion component and an enlarged grounding portion connected to the insertion component. The insertion component of the conductive piece is inserted into the hole of the circuit board and is electrically connected to the grounding pad, and a size of the enlarged grounding portion is larger than that of the hole.

### CROSS-REFERENCE TO RELATED APPLICATION

This application claims priority to Taiwan Application Serial Number 107107963, filed Mar. 8, 2018, which is herein incorporated by reference in its entirety.

### BACKGROUND

### Technical Field

The present disclosure relates to an electronic device, and in particular, to an electronic device that is manufactured conveniently and has a better anti-electromagnetic interference effect.

### Related Art

Currently, when an expansion card (for example, a mini PCI-E expansion card) is mounted onto a circuit board, one side of the expansion card is inserted into a connector on the circuit board, and the other side of the expansion card is further locked onto the circuit board by using a screw, so that the expansion card may be stably fixed to the circuit board. Therefore, a designer usually disposes a copper pillar having a screw hole at a location on the circuit board corresponding to the screw. However, if a plurality of screws needs to be used for fixing, correspondingly, a plurality of copper pillars needs to be disposed on the circuit board. In this case, a manufacturer needs to dispose the copper pillars on the circuit board one by one, making a manufacturing process relatively troublesome.

Moreover, usually, the designer disposes a grounding pad at a location on a circuit board corresponding to the copper pillars, and an expansion card is also designed to have a grounding pad at the location corresponding to the copper pillars, so that when the expansion card is fixed to the circuit board, the grounding pad of the expansion card can be in conductive communication with the grounding pad of the circuit board by using the copper pillar. However, limited by the size of the copper pillar, a grounding area that can be provided is relatively small, and an anti-electromagnetic interference effect of the expansion card is affected accordingly.

### SUMMARY

The present disclosure provides an electronic device that has a relatively convenient manufacturing process and can provide a preferable anti-electromagnetic interference effect.

An electronic device of the present disclosure includes a circuit board and a conductive piece. The circuit board includes a hole and a grounding pad close to the hole. The conductive piece includes an insertion component and an enlarged grounding portion connected to the insertion component. The insertion component of the conductive piece is inserted into the hole of the circuit board and is electrically connected to the grounding pad, and the size of the enlarged grounding portion is larger than that of two holes.

In an embodiment of the present disclosure, the enlarged grounding portion includes a top plate, and the top plate includes a fixing hole.

In an embodiment of the present disclosure, the top plate includes a through slot, and the through slot is located beside the fixing hole.

In an embodiment of the present disclosure, the enlarged grounding portion further includes a side wall extending from the top plate, and the insertion component extends from a position that is of the side wall and that is corresponding to one of fixing holes to a direction away from the top plate.

In an embodiment of the present disclosure, each insertion component includes a pin, and the insertion component corresponds to the fixing hole and extends from the side wall to the direction away from the top plate.

In an embodiment of the present disclosure, the circuit board further includes a connector, and the electronic device further includes: an expansion card. The expansion card is detachably inserted into the connector and abuts the enlarged grounding portion of the conductive piece.

In an embodiment of the present disclosure, the electronic device further includes a locking piece. The expansion card includes a through hole, and the locking piece is fixed to a fixing hole of the top plate through the through hole of the expansion card.

In an embodiment of the present disclosure, the expansion card includes an electronic element or a pad located beside the through hole, the top plate includes a through slot, and the electronic element or the pad of the expansion card corresponds to a position of the through slot of the conductive piece.

In an embodiment of the present disclosure, a distance between the connector and the hole is substantially the length of the expansion card.

In an embodiment of the present disclosure, the expansion card is a mini PCI-E expansion card.

Based on the foregoing description, in the electronic device of the present disclosure, the size of the enlarged grounding portion is larger than that of the hole of the circuit board, and compared with a conventional copper pillar, the conductive piece of the present disclosure can provide a larger grounding area in order to provide a better anti-electromagnetic interference effect.

To make the aforementioned characteristics and advantages of the present disclosure more comprehensible, embodiments are further described in detail hereinafter with reference to accompanying drawings.

### BRIEF DESCRIPTION OF THE DRAWINGS

FIG. 1 is a three-dimensional schematic diagram in which an expansion card of an electronic device has not been fixed by a locking piece according to an embodiment of the present disclosure;

FIG. 2 is a schematic diagram of a cross section along a line segment L1 when the expansion card of the electronic device in FIG. 1 is fixed by a locking piece to a circuit board;

FIG. 3 is a schematic diagram of a cross section along a line segment L2 when the expansion card of the electronic device in FIG. 1 is fixed by a locking piece to a circuit board;

FIG. 4 is a three-dimensional schematic diagram of a conductive piece of the electronic device in FIG. 1; and

FIG. 5 is a three-dimensional schematic diagram of a conductive piece according to an embodiment of the present disclosure.

### DETAILED DESCRIPTION

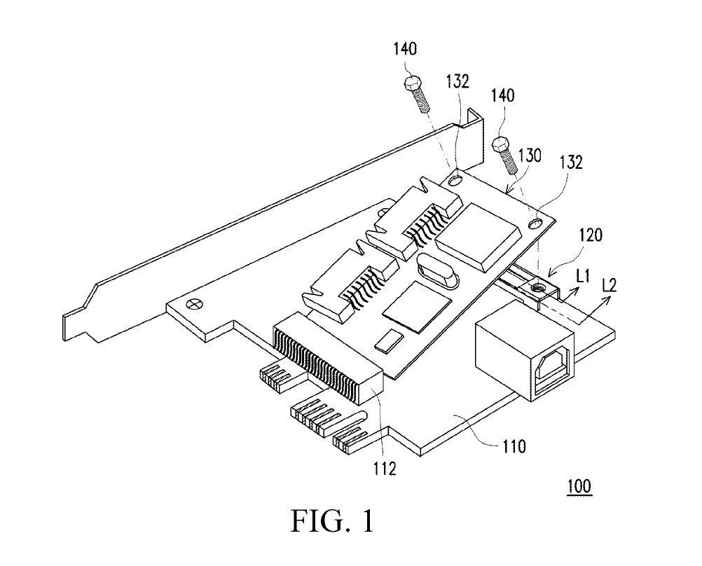

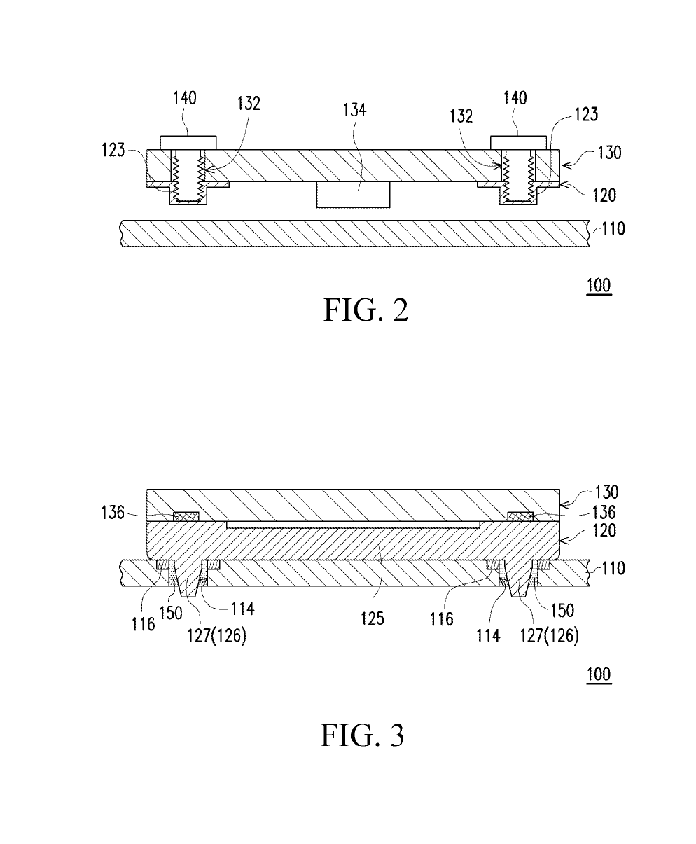

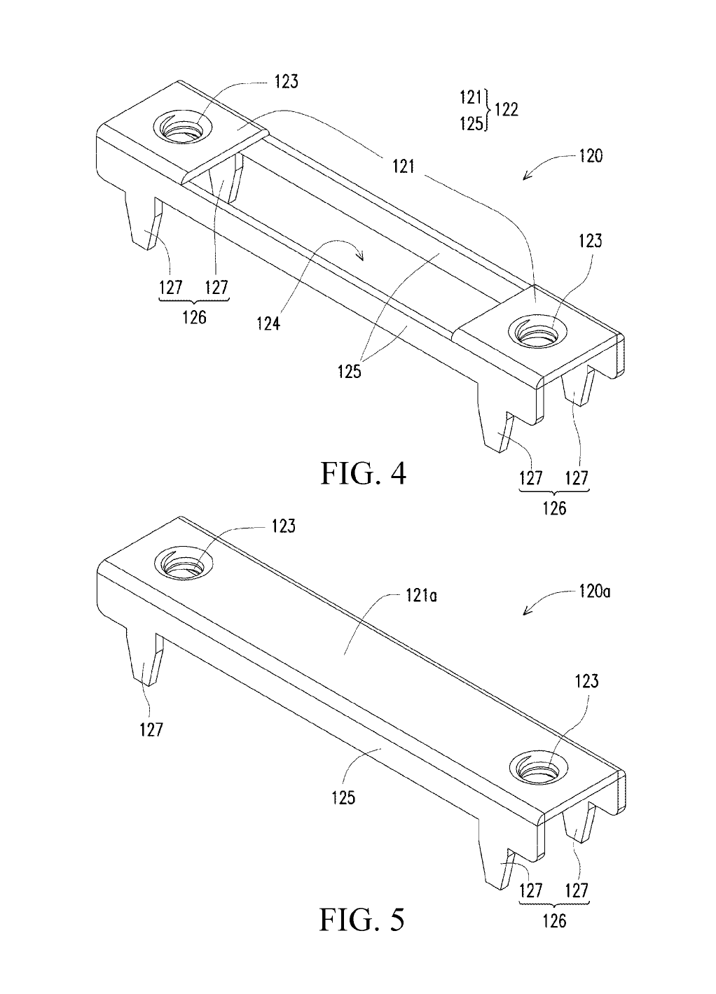

FIG. 1 is a three-dimensional schematic diagram in which an expansion card of an electronic device has not been fixed by a locking piece according to an embodiment of the present disclosure. FIG. 2 is a schematic diagram of a cross section along a line segment L1 when the expansion card of the electronic device in FIG. 1 is fixed by a locking piece to a circuit board. FIG. 3 is a schematic diagram of a cross section along a line segment L2 when the expansion card of the electronic device in FIG. 1 is fixed by a locking piece to a circuit board. FIG. 4 is a three-dimensional schematic diagram of a conductive piece of the electronic device in FIG. 1.

Referring to FIG. 1 to FIG. 4 together, in this embodiment, the electronic device 100 includes a circuit board 110, a conductive piece 120 fixedly disposed on the circuit board 110, an expansion card 130 that is detachably disposed on the circuit board 110 and that abuts the conductive piece 120, and at least one locking piece 140 that is used to fix the expansion card 130 to the conductive piece 120. In the electronic device 100 of this embodiment, a PCI-E expansion card is used as an example, and a mini PCI-E expansion card is used as an example of the expansion card 130. However, in other embodiments, the electronic device 100 may be another device such as a motherboard, the expansion card 130 may be an expansion card inserted into the motherboard, for example, a mini PCI-E expansion card, a PCI-E expansion card or an M.2 interface expansion card, and types of the electronic device 100 and the expansion card 130 are not limited thereto. Moreover, in this embodiment, a quantity of locking pieces 140 is, for example, two, and the locking pieces 140 are, for example, screws, but the quantity and the form of the locking pieces 140 are not limited thereto.

As shown in FIG. 1, the circuit board 110 includes a connector 112, for example, a connector 112 of a mini PCI-E interface, for the expansion card 130 to be inserted into and electrically connected to. Certainly, in other embodiments, a type of the connector 112 is not limited thereto, and the connector 112 may be a connector of USB, PCI-E, or M.2 interface. Moreover, as shown in FIG. 1, the expansion card 130 includes at least one through hole 132 on an opposite side of a connection side (not shown), for example, two through holes 132. When the expansion card 130 is mounted on the circuit board 110, the connection side of the expansion card 130 may be first inserted into the connector 112, and then the two locking pieces 140 are fixed to the conductive piece 120 through the two through holes 132 of the expansion card 130, to fix the expansion card 130 to the conductive piece 120.

As shown in FIG. 4, in this embodiment, the conductive piece 120 includes at least one insertion component 126 and an enlarged grounding portion 122 connected to the insertion component 126. A quantity of insertion components 126 is, for example, two, but is not limited thereto. The enlarged grounding portion 122 includes a top plate 121 and at least one side wall 125 extending from the top plate 121. In this embodiment, two side walls 125 extend from two opposite sides of the top plate 121, and the two insertion components 126 extend from the two side walls 125. The top plate 121 includes at least one fixing hole 123, for example, two fixing holes 123. FIG. 2 is a schematic diagram of a cross section along a line segment L1 in FIG. 1 when an expansion card 130 is fixed by locking pieces 140 to a circuit board 110. As shown in FIG. 2, the two fixing holes 123 of the top plate 121 are used for connection of the locking pieces 140. That is, the two locking pieces 140 may be passed through two through holes 132 of the expansion card 130 and then fixed to the two fixing holes 123 of the top plate 121, so that the expansion card 130 may be locked between the locking pieces 140 and the top plate 121. Please refer to FIG. 4, the two insertion components 126 respectively correspond to positions of the two fixing holes 123 and extend to a direction away from the top plate 121. In this embodiment, each insertion component 126 includes two pins 127 that respectively extend from opposite locations on the two side walls 125 to the direction away from the top plate 121. Certainly, the form and the quantity of the two insertion components 126 and the pins 127 or relative locations between the two insertion components 126 and these pins 127 are not limited to the foregoing description.

Please refer to FIG. 1 and FIG. 3, FIG. 3 is a schematic diagram of a cross section along a line segment L2 in FIG. 1 when the expansion card 130 is fixed by the locking piece 140 to the circuit board 110. In this embodiment, at a position away from the connector 112, the circuit board 110 further includes at least one group of holes 114 (for example, two groups of holes 114 shown in FIG. 3) and at least one group of grounding pads 116 (for example, two groups of grounding pads 116 shown in FIG. 3) close to the holes 114. In this embodiment, a distance between the connector 112 and the two holes 114 is substantially the length of the expansion card 130. Pins 127 of each insertion component 126 of the conductive piece 120 are respectively inserted into corresponding holes 114 on the circuit board 110, and the hole 114 may be filled with a solder 150 or other conductive material, so that the pins 127 of each insertion component 126 are electrically connected to the grounding pads 116, and the pins 127 can be stably fixed to the circuit board 110. Moreover, in this embodiment, the conductive piece 120 connects the two insertion components 126 together by using the top plate 121 and the two side walls 125, and the conductive piece 120 may be integrally manufactured, so that the two insertion components 126 of the conductive piece 120 can be inserted into the two holes 114 of the circuit board 110 together, and the steps and time for assembling the conductive piece 120 on the circuit board 110 may be effectively reduced.

It should be noted that, the size of a grounding area affects signal noise, and then affects an anti-electromagnetic interference (EMI) capability. Compared with using a copper pillar whose size is close to that of the hole 114 on the circuit board 110 as a grounding structure for clamping with the locking piece 140 in a conventional electronic device 100, in this embodiment, in addition to being used as a grounding structure at positions (which are close to the area of the conventional copper pillar) around the two fixing holes 123, the enlarged grounding portion 122 of the conductive piece 120 further includes a region of the top plate 121 other than the positions around the two fixing holes 123, and the two side walls 125, to provide a larger grounding area. In this embodiment, when the expansion card 130 is mounted on the circuit board 110, the grounding pad 116 of the expansion card 130 may abut the enlarged grounding portion 122 of the conductive piece 120 and be in conductive communication with the grounding pad 116 of the circuit board 110, and a grounding area provided by the enlarged grounding portion 122 of the conductive piece 120 may effectively improve an anti-electromagnetic interference effect. Certainly, in other embodiments, the form of the enlarged grounding portion 122 is not limited thereto, provided that the size or the area of the enlarged grounding portion 122 of the conductive piece 120 is larger than that of the two holes 114 of the circuit board 110.

Additionally, because the expansion card 130 may be provided with an electronic element 134 on a surface facing the circuit board 110, if a location of this electronic element 134 on the expansion card 130 corresponds to a location of the conductive piece 120, in a process of mounting the expansion card 130, the electronic element 134 may interfere with the conductive piece 120, such that the expansion card 130 cannot be mounted on the circuit board 110. As shown in FIG. 4, in this embodiment, the top plate 121 includes a through slot 124, and the through slot 124 is located beside the fixing hole 123. For example, the through slot 124 is located between two fixing holes 123 and separates the two fixing holes 123. As shown in FIG. 2, in this embodiment, the conductive piece 120 is provided with the through slot 124 arranged on the top plate 121, to make space and avoid interference. The expansion card 130 includes the electronic element 134 located on the surface facing the circuit board 110 (that is, a lower surface of the expansion card 130), and the electronic element 134 is, for example, a resistor, an inductor or a capacitor, but the type of the electronic element 134 is not limited thereto. In this embodiment, the electronic element 134 of the expansion card 130 is located beside the through hole 132, for example, located between the two through holes 132, and corresponds to the position of the through slot 124 of the conductive piece 120. Therefore, when the expansion card 130 is mounted on the circuit board 110, the electronic element 134 of the expansion card 130 is extended to a location between the two side walls 125 of the conductive piece 120 through the through slot 124 of the conductive piece 120, so that interference between the electronic element 134 of the expansion card 130 and the top plate 121 of the conductive piece 120 may be avoided.

Certainly, in other embodiments, the expansion card 130 may include a pad (not shown) or a circuit (not shown) between the two through holes 132, and the through slot 124 provided on the top plate 121 may prevent the pad or the circuit of the expansion card 130 from being directly contact with the top plate 121 to be short-circuited. It should be noted that, in this embodiment, a rectangular slot is used as an example of the through slot 124, but in other embodiments, the shape and the range of the through slot 124 are not limited thereto.

Certainly, in other embodiments, the forms of the conductive piece 120 and the enlarged grounding portion 122 are not limited thereto. FIG. 5 is a three-dimensional schematic diagram of a conductive piece according to an embodiment of the present disclosure. Referring to FIG. 5, a main difference between the conductive piece 120a in FIG. 5 and the conductive piece 120 in FIG. 4 is that, in this embodiment, a top plate 121a of the conductive piece 120a does not have a through slot located between two fixing holes 123. If there is no electronic element or a pad between two through holes on the expansion card that is fixed on the conductive piece 120a so that the conductive piece 120a does not need to make space on the top plate 121a, the top plate 121a of the conductive piece 120a may be designed without a through slot. In this way, the conductive piece 120a may further provide a larger grounding area and may provide a good anti-electromagnetic interference effect.

To sum up, in the electronic device of the present disclosure, the size or the area of the enlarged grounding portion is larger than that of the hole of the circuit board. Since the enlarged grounding portion of the conductive piece is connected beside the insertion component, for example, connected between the two insertion components, and in an embodiment, a part of the enlarged grounding portion further extends from a hole of the circuit board to another hole. Therefore, compared with the conventional copper pillar, the conductive piece of the present disclosure can provide a larger grounding area, and then may provide a better anti-electromagnetic interference effect. Moreover, the conductive piece of the electronic device of the present disclosure is connected to the two insertion components by using the enlarged grounding portion, so that the two insertion components of the conductive piece can be inserted into the two holes of the circuit board together, and the steps and time for fixing the conductive piece to the circuit board may be effectively reduced.

Although the present disclosure is disclosed with reference to embodiments above, the embodiments are not intended to limit the present disclosure. Any person of ordinary skill in the art may make some variations and modifications without departing from the spirit and scope of the disclosure, and therefore, the protection scope of the present disclosure should be defined in the following claims.

What is claimed is:

1. An electronic device, comprising:
a circuit board, comprising a hole and a grounding pad close to the hole; and
a conductive piece, comprising an insertion component and an enlarged grounding portion connected to the insertion component, wherein the insertion component is inserted into the hole of the circuit board and is electrically connected to the grounding pad, and a size of the enlarged grounding portion is larger than a size of the hole.

2. The electronic device according to claim 1, wherein the enlarged grounding portion comprises a top plate, and the top plate comprises a fixing hole.

3. The electronic device according to claim 2, wherein the top plate comprises a through slot, and the through slot is located beside the fixing hole.

4. The electronic device according to claim 2, wherein the enlarged grounding portion further comprises a side wall extending from the top plate, and the insertion component corresponds to the fixing hole and extends from the side wall to a direction away from the top plate.

5. The electronic device according to claim 4, wherein the insertion component comprises a pin, extending from the side wall to the direction away from the top plate.

6. The electronic device according to claim 1, wherein the circuit board further comprises a connector, and the electronic device further comprises:
an expansion card, detachably inserted into the connector and abutting the enlarged grounding portion of the conductive piece.

7. The electronic device according to claim 6, further comprising:
a locking piece, wherein the expansion card comprises a through hole, and the locking piece is fixed to a fixing hole of the top plate through the through hole of the expansion card.

8. The electronic device according to claim 7, wherein the expansion card comprises an electronic element or a pad located beside the through hole, the top plate comprises a through slot, and the electronic element or the pad of the expansion card corresponds to a position of the through slot of the conductive piece.

9. The electronic device according to claim 6, wherein a distance between the connector and the hole is the length of the expansion card.

10. The electronic device according to claim 1, wherein the expansion card is a mini PCI-E expansion card.
